(19) United States
(12) Patent Application Publication
(10) Pub. No.: US 2021/0364924 A1
(43) Pub. Date: Nov. 25, 2021

(54) PHOTORESIST DEVELOPER AND METHOD OF MANUFACTURING A SEMICONDUCTOR DEVICE

(71) Applicant: TAIWAN SEMICONDUCTOR MANUFACTURING COMPANY, LTD., Hsinchu (TW)

(72) Inventors: Chen-Yu LIU, Kaohsiung City (TW); Ming-Hui WENG, New Taipei City (TW); An-Ren ZI, Hsinchu City (TW); Ching-Yu CHANG, Yuansun Village (TW); Chin-Hsiang LIN, Hsinchu (TW)

(21) Appl. No.: 17/246,427

(22) Filed: Apr. 30, 2021

Related U.S. Application Data
(60) Provisional application No. 63/028,516, filed on May 21, 2020.

(51) Int. Cl. G03F 7/32; H01L 21/027; H01L 21/308

(52) U.S. Cl. CPC G03F 7/32; H01L 21/3086; H01L 21/0274

(57) ABSTRACT

A method of manufacturing a semiconductor device includes forming a photoresist layer over a substrate and selectively exposing the photoresist layer to actinic radiation to form a latent pattern. The latent pattern is developed by applying a developer composition to the selectively exposed photoresist layer to form a pattern in the photoresist layer. The developer composition includes: a first solvent having Hansen solubility parameters of 18>δ_{d}>3, 7>δₚ>1, and 7>δₕ>1; an organic acid having an acid dissociation constant, pKa, of −11<pKa<4; and a Lewis acid, wherein the organic acid and the Lewis acid are different.

### RELATED APPLICATION

This application claims priority to U.S. Provisional Patent Application No. 63/028,516 filed May 21, 2020, the entire content of which is incorporated herein by reference.

### BACKGROUND

As consumer devices have gotten smaller and smaller in response to consumer demand, the individual components of these devices have necessarily decreased in size as well. Semiconductor devices, which make up a major component of devices such as mobile phones, computer tablets, and the like, have been pressured to become smaller and smaller, with a corresponding pressure on the individual devices (e.g., transistors, resistors, capacitors, etc.) within the semiconductor devices to also be reduced in size.

One enabling technology that is used in the manufacturing processes of semiconductor devices is the use of photolithographic materials. Such materials are applied to a surface of a layer to be patterned and then exposed to an energy that has itself been patterned. Such an exposure modifies the chemical and physical properties of the exposed regions of the photosensitive material. This modification, along with the lack of modification in regions of the photosensitive material that were not exposed, can be exploited to remove one region without removing the other, or vice-verse.

However, as the size of individual devices has decreased, process windows for photolithographic processing has become tighter and tighter. As such, advances in the field of photolithographic processing are necessary to maintain the ability to scale down the devices, and further improvements are needed in order to meet the desired design criteria such that the march towards smaller and smaller components may be maintained.

As the semiconductor industry has progressed into nanometer technology process nodes in pursuit of higher device density, higher performance, and lower costs, there have been challenges in reducing semiconductor feature size.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a process flow of manufacturing a semiconductor device according to embodiments of the disclosure.

FIG. 2 shows a process stage of a sequential operation according to an embodiment of the disclosure.

FIGS. 3A and 3B show a process stage of a sequential operation according to an embodiment of the disclosure.

FIG. 4 shows a process stage of a sequential operation according to an embodiment of the disclosure.

FIG. 5 shows a process stage of a sequential operation according to an embodiment of the disclosure.

FIG. 6 shows a process stage of a sequential operation according to an embodiment of the disclosure.

FIG. 7A shows organometallic precursors according to embodiments of the disclosure.

FIG. 7B shows a reaction the organometallic precursors undergo when exposed to actinic radiation. FIG. 7C shows examples of organometallic precursors according to embodiments of the disclosure.

FIG. 8 shows a resist deposition apparatus according to embodiments of the disclosure.

FIG. 9 shows a reaction the photoresist composition components undergo as a result of exposure to actinic radiation and heating according to an embodiment of the disclosure.

FIG. 10 shows a developer reaction according to embodiments of the disclosure.

FIG. 11 shows a process stage of a sequential operation according to an embodiment of the disclosure.

FIGS. 12A and 12B show a process stage of a sequential operation according to an embodiment of the disclosure.

FIG. 13 shows a process stage of a sequential operation according to an embodiment of the disclosure.

FIG. 14 shows a process stage of a sequential operation according to an embodiment of the disclosure.

FIG. 15 shows a process stage of a sequential operation according to an embodiment of the disclosure.

FIG. 16 shows a process stage of a sequential operation according to an embodiment of the disclosure.

FIG. 17 shows a process stage of a sequential operation according to an embodiment of the disclosure.

FIG. 18 shows a process stage of a sequential operation according to an embodiment of the disclosure.

FIG. 19 shows a process stage of a sequential operation according to an embodiment of the disclosure.

FIG. 20 illustrates a process flow of manufacturing a semiconductor device according to embodiments of the disclosure.

### DETAILED DESCRIPTION

It is to be understood that the following disclosure provides many different embodiments, or examples, for implementing different features of the disclosure. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of”

Resist scum and residue remaining in the patterned areas of the photoresist layer after development causes increased line width roughness and line etch roughness. The scum and residue causes defects in photoresist patterns and results in decreased semiconductor device yield. Embodiments of the present disclosure address these issues, and reduce the amount of scum and residue or substantially eliminate scum and residue after development.

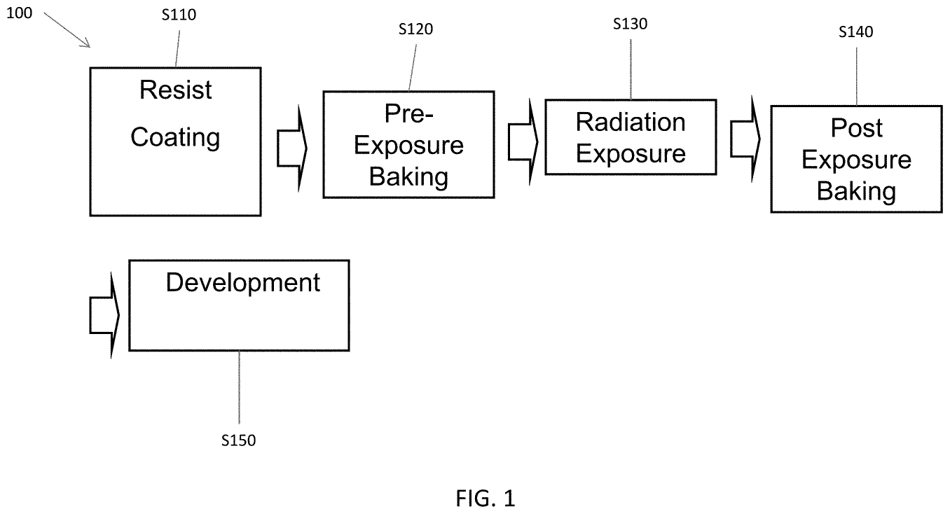

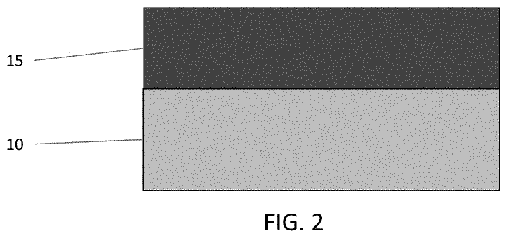

FIG. 1 illustrates a process flow 100 of manufacturing a semiconductor device according to embodiments of the disclosure. A resist is coated on a surface of a layer to be patterned or a substrate 10 in operation S110, in some embodiments, to form a resist layer 15, as shown in FIG. 2. In some embodiments, the resist is a metal-containing photoresist formed by chemical vapor deposition (CVD) or atomic layer deposition (ALD). In some embodiments, the metal-containing photoresist layer is formed by a spin-coating method.

Then the resist layer 15 undergoes a first baking (or pre-exposure baking) operation S120 to evaporate solvents in the resist composition in some embodiments. The resist layer 15 is baked at a temperature and time sufficient to cure and dry the resist layer 15. In some embodiments, the resist layer 15 is heated at a temperature of about 40° C. and 120° C. for about 10 seconds to about 10 minutes.

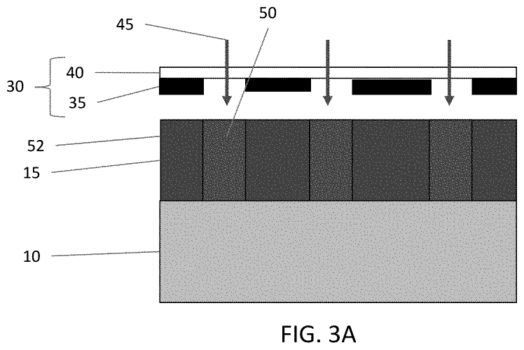

The resist layer 15 is selectively exposed to actinic radiation 45 (see FIGS. 3A and 3B) in operation S130. In some embodiments, the resist layer 15 is selectively exposed to ultraviolet radiation. In some embodiments, the ultraviolet radiation is deep ultraviolet radiation. In some embodiments, the ultraviolet radiation is extreme ultraviolet (EUV) radiation. In some embodiments, the radiation is an electron beam.

As shown in FIG. 3A, the exposure radiation 45 passes through a photomask 30 before irradiating the resist layer 15 in some embodiments. In some embodiments, the photomask has a pattern to be replicated in the resist layer 15. The pattern is formed by an opaque pattern 35 on photomask substrate 40, in some embodiments. The opaque pattern 35 may be formed by a material opaque to ultraviolet radiation, such as chromium, while the photomask substrate 40 is formed of a material that is transparent to ultraviolet radiation, such as fused quartz.

In some embodiments, the selective exposure of the photoresist layer 15 to form exposed regions 50 and unexposed regions 52 is performed using extreme ultraviolet lithography. In an extreme ultraviolet lithography operation a reflective photomask 65 is used to form the patterned exposure light in some embodiments, as shown in FIG. 3B. The reflective photomask 65 includes a low thermal expansion glass substrate 70, on which a reflective multilayer 75 of Si and Mo is formed. A capping layer 80 and absorber layer 85 are formed on the reflective multilayer 75. A rear conductive layer 90 is formed on the back side of the low thermal expansion substrate 70. In extreme ultraviolet lithography, extreme ultraviolet radiation 95 is directed towards the reflective photomask 65 at an incident angle of about 6°. A portion 97 of the extreme ultraviolet radiation is reflected by the Si/Mo multilayer 75 towards the photoresist-coated substrate 10, while the portion of the extreme ultraviolet radiation incident upon the absorber layer 85 is absorbed by the photomask. In some embodiments, additional optics, including mirrors, are between the reflective photomask 65 and the photoresist-coated substrate.

In some embodiments, the resist layer 15 is a photoresist layer. The region of the photoresist layer 15 exposed to radiation 50 undergoes a chemical reaction thereby changing its solubility in a subsequently applied developer relative to the region of the photoresist layer not exposed to radiation 52. In some embodiments, the portion of the photoresist layer exposed to radiation 50 undergoes a crosslinking reaction.

The amount of electromagnetic radiation the photoresist layer 15 is exposed to can be characterized by a fluence or dose, which is obtained by the integrated radiative flux over the exposure time. Suitable radiation fluences range from about 1 mJ/cm² to about 150 mJ/cm² in some embodiments, from about 2 mJ/cm² to about 100 mJ/cm² in other embodiments, and from about 3 mJ/cm² to about 50 mJ/cm² in other embodiments. A person of ordinary skill in the art will recognize that additional ranges of radiation fluences within the explicit ranges above are contemplated and are within the present disclosure.

In some embodiments, the selective or patternwise exposure is performed by a scanning electron beam. With electron beam lithography, the electron beam induces secondary electrons, which modify the irradiated material. High resolution is achievable using electron beam lithography and the metal-containing resists disclosed herein. Electron beams can be characterized by the energy of the beam, and suitable energies range from about 5 V to about 200 kV (kilovolt) in some embodiments, and from about 7.5 V to about 100 kV in other embodiments. Proximity-corrected beam doses at 30 kV range from about 0.1 μC/cm² to about 5 μC/cm² in some embodiments, from about 0.5 μC/cm² to about 1 μC/cm² in other embodiments, and in other embodiments from about 1 μC/cm² to about 100 μC/cm². A person of ordinary skill in the art can compute corresponding doses at other beam energies based on the teachings herein and will recognize that additional ranges of electron beam properties within the explicit ranges above are contemplated and are within the present disclosure.

Next, the resist layer 15 undergoes a heating or a post-exposure bake (PEB) in operation S140. In some embodiments, the resist layer 15 is heated at a temperature of about 50° C. to about 250° C. for about 20 seconds to about 300 seconds. In some embodiments, the post-exposure baking is performed at a temperature ranging from about 100° C. to about 230° C., and at a temperature ranging from about 150° C. to about 200° C. in other embodiments. In some embodiments, the post-exposure baking operation S140 causes the reaction product of a first compound or first precursor and a second compound or second precursor in the resist layer 15 that was exposed to actinic operation in operation S130 to further crosslink.

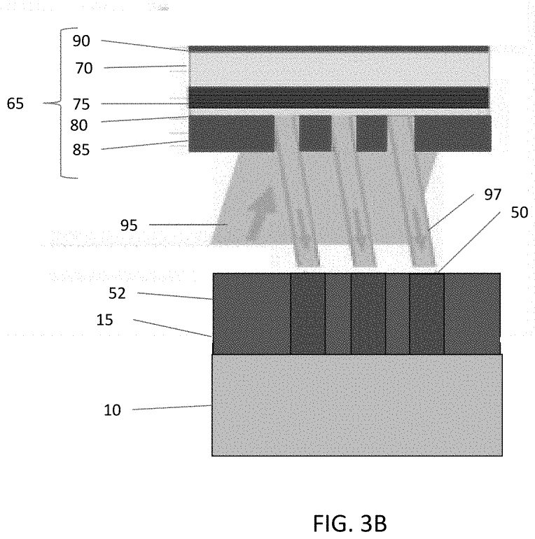

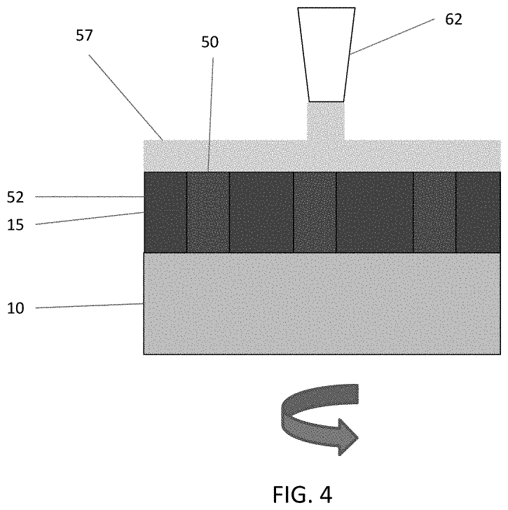

The selectively exposed resist layer is subsequently developed by applying a developer to the selectively exposed resist layer in operation S150. As shown in FIG. 4, a developer 57 is supplied from a dispenser 62 to the resist layer 15. In some embodiments, the unexposed portion of the resist layer 52 is removed by the developer 57 forming a pattern of openings 55 in the resist layer 15 to expose the substrate 20, as shown in FIG. 5.

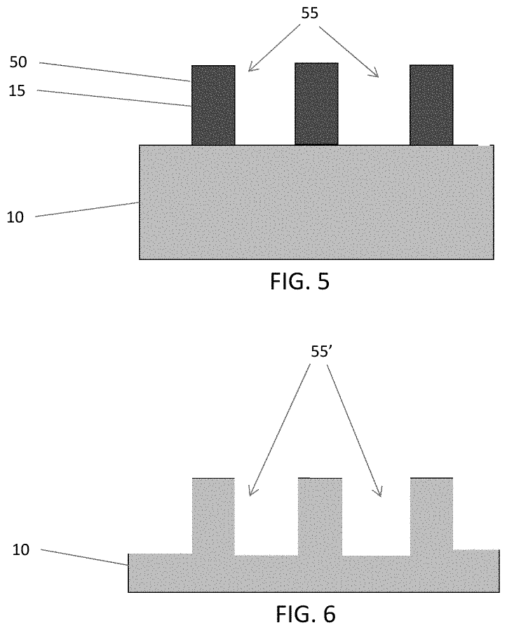

In some embodiments, the pattern of openings 55 in the resist layer 15 are extended into the layer to be patterned or substrate 10 to create a pattern of openings 55′ in the substrate 10, thereby transferring the pattern in the photoresist layer 15 into the substrate 10, as shown in FIG. 6. The pattern is extended into the substrate by etching, using one or more suitable etchants. The exposed resist layer 15 is at least partially removed during the etching operation in some embodiments. In other embodiments, the exposed resist layer 15 is removed after etching the substrate 10 by using a suitable photoresist stripper solvent or by a photoresist ashing operation.

In some embodiments, the substrate 10 includes a single crystalline semiconductor layer on at least it surface portion. The substrate 10 may include a single crystalline semiconductor material such as, but not limited to Si, Ge, SiGe, GaAs, InSb, GaP, GaSb, InAlAs, InGaAs, GaSbP, GaAsSb and InP. In some embodiments, the substrate 10 is a silicon layer of an SOI (silicon-on insulator) substrate. In certain embodiments, the substrate 10 is made of crystalline Si.

The substrate 10 may include in its surface region, one or more buffer layers (not shown). The buffer layers can serve to gradually change the lattice constant from that of the substrate to that of subsequently formed source/drain regions. The buffer layers may be formed from epitaxially grown single crystalline semiconductor materials such as, but not limited to Si, Ge, GeSn, SiGe, GaAs, InSb, GaP, GaSb, InAlAs, InGaAs, GaSbP, GaAsSb, GaN, GaP, and InP. In an embodiment, the silicon germanium (SiGe) buffer layer is epitaxially grown on the silicon substrate 10. The germanium concentration of the SiGe buffer layers may increase from 30 atomic % for the bottom-most buffer layer to 70 atomic % for the top-most buffer layer.

In some embodiments, the substrate 10 includes at least one metal, metal alloy, and metal nitride/sulfide/oxide/silicide having the formula MXₐ, where M is a metal and X is N, S, Se, O, Si, and a is from about 0.4 to about 2.5. In some embodiments, the substrate 10 includes titanium, aluminum, cobalt, ruthenium, titanium nitride, tungsten nitride, tantalum nitride, and combinations thereof.

In some embodiments, the substrate 10 includes a dielectric having at least silicon, metal oxide, and metal nitride of the formula MX_{b}, where M is a metal or Si, X is N or O, and b ranges from about 0.4 to about 2.5. In some embodiments, the substrate 10 includes silicon dioxide, silicon nitride, aluminum oxide, hafnium oxide, lanthanum oxide, and combinations thereof.

The photoresist layer 15 is a photosensitive layer that is patterned by exposure to actinic radiation. Typically, the chemical properties of the photoresist regions struck by incident radiation change in a manner that depends on the type of photoresist used. The photoresists are positive tone resists or negative tone resists. A positive tone resist refers to a photoresist material that when exposed to radiation (e.g. —UV light) becomes soluble in a developer, while the region of the photoresist that is non-exposed (or exposed less) is insoluble in the developer. A negative tone resist, on the other hand, refers to a photoresist material that when exposed to radiation becomes insoluble in the developer, while the region of the photoresist that is non-exposed (or exposed less) is soluble in the developer. The region of a negative tone resist that becomes insoluble upon exposure to radiation may become insoluble due to a cross-linking reaction caused by the exposure to radiation. In some embodiments, the resist is a negative tone developed (NTD) resist. In an NTD resist, instead of the portion of the resist exposed to actinic radiation crosslinking, a developer solvent is selected that preferentially dissolves the unexposed portion of the resist to form the patterned resist.

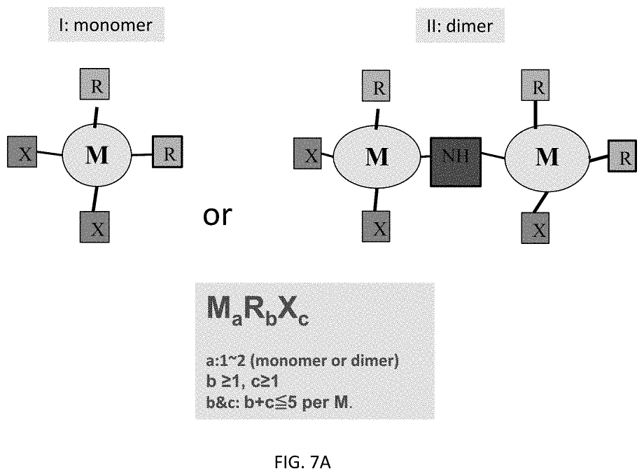

In some embodiments, the photoresist layer 15 is made of a photoresist composition, including a first compound or a first precursor and a second compound or a second precursor combined in a vapor state. The first precursor or first compound is an organometallic having a formula: MₐR_{b}X_{c}, as shown in FIG. 7A, where M is at least one of Sn, Bi, Sb, In, Te, Ti, Zr, Hf, V, Co, Mo, W, Al, Ga, Si, Ge, P, As, Y, La, Ce, or Lu; and R is a substituted or unsubstituted alkyl, alkenyl, or carboxylate group. In some embodiments, M is selected from the group consisting of Sn, Bi, Sb, In, Te, and combinations thereof. In some embodiments, R is a C3-C6 alkyl, alkenyl, or carboxylate. In some embodiments, R is selected from the group consisting of propyl, isopropyl, butyl, iso-butyl, sec-butyl, tert-butyl, pentyl, isopentyl, sec-pentyl, tert-pentyl, hexyl, iso-hexyl, sec-hexyl, tert-hexyl, and combinations thereof. X is a ligand, ion, or other moiety, which is reactive with the second compound or second precursor; and 1≤a≤2, b≥1, c≥1, and b+c≤5 in some embodiments. In some embodiments, the alkyl, alkenyl, or carboxylate group is substituted with one or more fluoro groups. In some embodiments, the organometallic precursor is a dimer, as shown in FIG. 7A, where each monomer unit is linked by an amine group. Each monomer has a formula: MₐR_{b}X_{c}, as defined above.

In some embodiments, R is alkyl, such as CₙH₂ₙ₊₁ where n≥3. In some embodiments, R is fluorinated, e.g., having the formula CₙFₓH₍₍₂ₙ₊₁₎₋ₓ₎. In some embodiments, R has at least one beta-hydrogen or beta-fluorine. In some embodiments, R is selected from the group consisting of i-propyl, n-propyl, t-butyl, i-butyl, n-butyl, sec-butyl, n-pentyl, i-pentyl, t-pentyl, and sec-pentyl, and combinations thereof.

In some embodiments, X is any moiety readily displaced by the second compound or second precursor to generate an M-OH moiety, such as a moiety selected from the group consisting of amines, including dialkylamino and monalkylamino; alkoxy; carboxylates, halogens, and sulfonates. In some embodiments, the sulfonate group is substituted with one or more amine groups. In some embodiments, the halide is one or more selected from the group consisting of F, Cl, Br, and I. In some embodiments, the sulfonate group includes a substituted or unsubstituted C1-C3 group.

In some embodiments, the first organometallic compound or first organometallic precursor includes a metallic core M⁺ with ligands L attached to the metallic core M⁺, as shown in FIG. 7B. In some embodiments, the metallic core M⁺ is a metal oxide. The ligands L include C3-C12 aliphatic or aromatic groups in some embodiments. The aliphatic or aromatic groups may be unbranched or branched with cyclic, or noncyclic saturated pendant groups containing 1-9 carbons, including alkyl groups, alkenyl groups, and phenyl groups. The branched groups may be further substituted with oxygen or halogen. In some embodiments, the C3-C12 aliphatic or aromatic groups include heterocyclic groups. In some embodiments, the C3-C12 aliphatic or aromatic groups are attached to the metal by an ether or ester linkage. In some embodiments, the C3-C12 aliphatic or aromatic groups include nitrite and sulfonate substituents.

In some embodiments, the organometallic precursor or organometallic compound include a sec-hexyl tris(dimethylamino) tin, t-hexyl tris(dimethylamino) tin, i-hexyl tris(dimethylamino) tin, n-hexyl tris(dimethylamino) tin, sec-pentyl tris(dimethylamino) tin, t-pentyl tris(dimethylamino) tin, i-pentyl tris(dimethylamino) tin, n-pentyl tris(dimethylamino) tin, sec-butyl tris(dimethylamino) tin, t-butyl tris(dimethylamino) tin, i-butyl tris(dimethylamino) tin, n-butyl tris(dimethylamino) tin, sec-butyl tris(dimethylamino) tin, i-propyl(tris)dimethylamino tin, n-propyl tris(diethylamino) tin, and analogous alkyl(tris)(t-butoxy) tin compounds, including sec-hexyl tris(t-butoxy) tin, t-hexyl tris(t-butoxy) tin, i-hexyl tris(t-butoxy) tin, n-hexyl tris(t-butoxy) tin, sec-pentyl tris(t-butoxy), t-pentyl tris(t-butoxy) tin, i-pentyl tris(t-butoxy) tin, n-pentyl tris(t-butoxy) tin, t-butyl tris(t-butoxy) tin, i-butyl tris(butoxy) tin, n-butyl tris(butoxy) tin, sec-butyl tris(butoxy) tin, i-propyl(tris)dimethylamino tin, or n-propyl tris(butoxy) tin. In some embodiments, the organometallic precursors or organometallic compounds are fluorinated. In some embodiments, the organometallic precursors or compounds have a boiling point less than about 200° C.

In some embodiments, the first compound or first precursor includes one or more unsaturated bonds that can be coordinated with a functional group, such as a hydroxyl group, on the surface of the substrate or an intervening underlayer to improve adhesion of the photoresist layer to the substrate or underlayer.

In some embodiments, the second precursor or second compound is at least one of an amine, a borane, a phosphine, or water. In some embodiments, the amine has a formula NₚHₙXₘ, where 0≤n≤3, 0≤m≤3, n+m=3 when p is 1, and n+m=4 when p is 2, and each X is independently a halogen selected from the group consisting of F, Cl, Br, and I. In some embodiments, the borane has a formula BₚHₙXₘ, where 0≤n≤3, 0≤m≤3, n+m=3 when p is 1, and n+m=4 when p is 2, and each X is independently a halogen selected from the group consisting of F, Cl, Br, and I. In some embodiments, the phosphine has a formula PₚHₙXₘ, where 0≤n≤3, 0≥m≤3, n+m=3, when p is 1, or n+m=4 when p is 2, and each X is independently a halogen selected from the group consisting of F, Cl, Br, and I.

FIG. 7B shows metallic precursors undergoing a reaction as a result of exposure to actinic radiation in some embodiments. As a result of exposure to the actinic radiation, ligand groups L are split off from the metallic core M⁺ of the metallic precursors, and two or more metallic precursor cores bond with each other.

FIG. 7C shows examples of organometallic precursors according to embodiments of the disclosure. In FIG. 7C, Bz is a benzene group.

In some embodiments, the operation S110 of depositing a photoresist composition is performed by a vapor phase deposition operation. In some embodiments, the vapor phase deposition operation includes atomic layer deposition (ALD) or chemical vapor deposition (CVD). In some embodiments, the ALD includes plasma-enhanced atomic layer deposition (PE-ALD), and the CVD includes plasma-enhanced chemical vapor deposition (PE-CVD), metal-organic chemical vapor deposition (MO-CVD); atmospheric pressure chemical vapor deposition (AP-CVD), and low pressure chemical vapor deposition (LP-CVD).

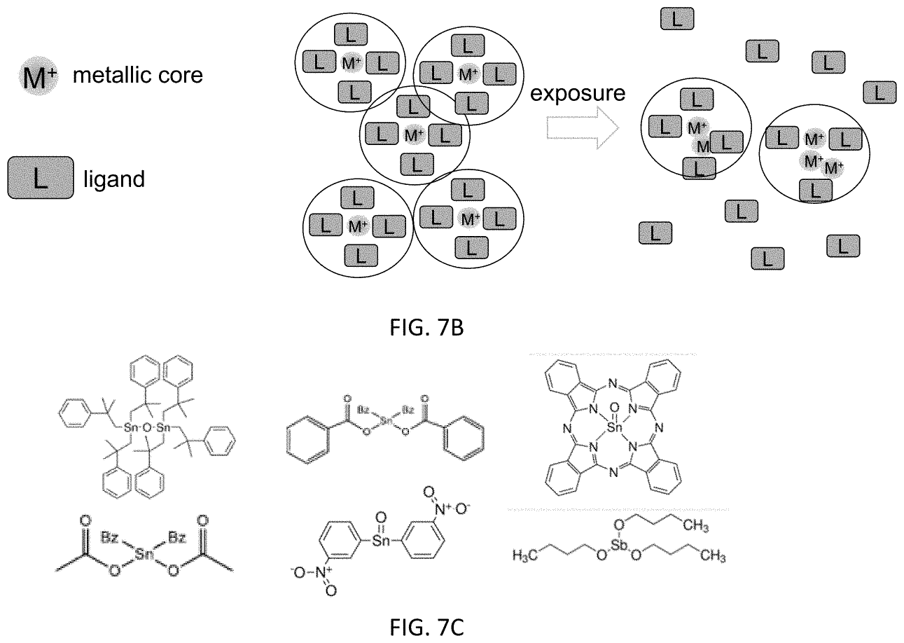

A resist layer deposition apparatus 200 according to some embodiments of the disclosure is shown in FIG. 8. In some embodiments, the deposition apparatus 200 is an ALD or CVD apparatus. The deposition apparatus 200 includes a vacuum chamber 205. A substrate support stage 210 in the vacuum chamber 205 supports a substrate 10, such as silicon wafer. In some embodiments, the substrate support stage 210 includes a heater. A first precursor or compound gas supply 220 and carrier/purge gas supply 225 are connected to an inlet 230 in the chamber via a gas line 235, and a second precursor or compound gas supply 240 and carrier/purge gas supply 225 are connected to another inlet 230′ in the chamber via another gas line 235′ in some embodiments. The chamber is evacuated, and excess reactants and reaction byproducts are removed by a vacuum pump 245 via an outlet 250 and exhaust line 255. In some embodiments, the flow rate or pulses of precursor gases and carrier/purge gases, evacuation of excess reactants and reaction byproducts, pressure inside the vacuum chamber 205, and temperature of the vacuum chamber 205 or wafer support stage 210 are controlled by a controller 260 configured to control each of these parameters.

Depositing a photoresist layer includes combining the first compound or first precursor and the second compound or second precursor in a vapor state to form the photoresist composition. In some embodiments, the first compound or first precursor and the second compound or second precursor of the photoresist composition are introduced into the deposition chamber 205 (CVD chamber) at about the same time via the inlets 230, 230′. In some embodiments, the first compound or first precursor and second compound or second precursor are introduced into the deposition chamber 205 (ALD chamber) in an alternating manner via the inlets 230, 230′, i.e.—first one compound or precursor then a second compound or precursor, and then subsequently alternately repeating the introduction of the one compound or precursor followed by the second compound or precursor.

In some embodiments, the deposition chamber temperature ranges from about 30° C. to about 400° C. during the deposition operation, and between about 50° C. to about 250° C. in other embodiments. In some embodiments, the pressure in the deposition chamber ranges from about 5 mTorr to about 100 Torr during the deposition operation, and between about 100 mTorr to about 10 Torr in other embodiments. In some embodiments, the plasma power is less than about 1000 W. In some embodiments, the plasma power ranges from about 100 W to about 900 W. In some embodiments, the flow rate of the first compound or precursor and the second compound or precursor ranges from about 100 sccm to about 1000 sccm. In some embodiments, the ratio of the flow of the organometallic compound precursor to the second compound or precursor ranges from about 1:1 to about 1:5. At operating parameters outside the above-recited ranges, unsatisfactory photoresist layers result in some embodiments. In some embodiments, the photoresist layer formation occurs in a single chamber (a one-pot layer formation).

In a CVD process according to some embodiments of the disclosure, two or more gas streams, in separate inlet paths 230, 235 and 230′, 235′, of an organometallic precursor and a second precursor are introduced to the deposition chamber 205 of a CVD apparatus, where they mix and react in the gas phase, to form a reaction product. The streams are introduced using separate injection inlets 230, 230′ or a dual-plenum showerhead in some embodiments. The deposition apparatus is configured so that the streams of organometallic precursor and second precursor are mixed in the chamber, allowing the organometallic precursor and second precursor to react to form a reaction product. Without limiting the mechanism, function, or utility of the disclosure, it is believed that the product from the vapor-phase reaction becomes heavier in molecular weight, and is then condensed or otherwise deposited onto the substrate 10.

In some embodiments, an ALD process is used to deposit the photoresist layer. During ALD, a layer is grown on a substrate 10 by exposing the surface of the substrate to alternate gaseous compounds (or precursors). In contrast to CVD, the precursors are introduced as a series of sequential, non-overlapping pulses. In each of these pulses, the precursor molecules react with the surface in a self-limiting way, so that the reaction terminates once all the reactive sites on the surface are consumed. Consequently, the maximum amount of material deposited on the surface after a single exposure to all of the precursors (a so-called ALD cycle) is determined by the nature of the precursor-surface interaction.

In an embodiment of an ALD process, an organometallic precursor is pulsed to deliver the metal-containing precursor to the substrate 10 surface in a first half reaction. In some embodiments, the organometallic precursor reacts with a suitable underlying species (for example OH or NH functionality on the surface of the substrate) to form a new self-saturating surface. Excess unused reactants and the reaction by-products are removed, by an evacuation-pump down using a vacuum pump 245 and/or by a flowing an inert purge gas in some embodiments. Then, a second precursor, such as ammonia (NH₃), is pulsed to the deposition chamber in some embodiments. The NH₃ reacts with the organometallic precursor on the substrate to obtain a reaction product photoresist on the substrate surface. The second precursor also forms self-saturating bonds with the underlying reactive species to provide another self-limiting and saturating second half reaction. A second purge is performed to remove unused reactants and the reaction by-products in some embodiments. Pulses of the first precursor and second precursor are alternated with intervening purge operations until a desired thickness of the photoresist layer is achieved.

In some embodiments, the photoresist layer 15 is formed to a thickness of about 5 nm to about 50 nm, and to a thickness of about 10 nm to about 30 nm in other embodiments. A person of ordinary skill in the art will recognize that additional ranges of thicknesses within the explicit ranges above are contemplated and are within the present disclosure. The thickness can be evaluated using non-contact methods of x-ray reflectivity and/or ellipsometry based on the optical properties of the photoresist layers. In some embodiments, each photoresist layer thickness is relatively uniform to facilitate processing. In some embodiments, the variation in thickness of the deposited photoresist layer varies by no more than +25% from the average thickness, in other embodiments each photoresist layer thickness varies by no more than +10% from the average photoresist layer thickness. In some embodiments, such as high uniformity depositions on larger substrates, the evaluation of the photoresist layer uniformity may be evaluated with a 1 centimeter edge exclusion, i.e., the layer uniformity is not evaluated for portions of the coating within 1 centimeter of the edge. A person of ordinary skill in the art will recognize that additional ranges within the explicit ranges above are contemplated and are within the present disclosure.

In some embodiments, the first and second compounds or precursors are delivered into the deposition chamber 205 with a carrier gas. The carrier gas, a purge gas, a deposition gas, or other process gas may contain nitrogen, hydrogen, argon, neon, helium, or combinations thereof.

In some embodiments, the organometallic compound includes tin (Sn), antimony (Sb), bismuth (Bi), indium (In), and/or tellurium (Te) as the metal component, however, the disclosure is not limited to these metals. In other embodiments, additional suitable metals include titanium (Ti), zirconium (Zr), hafnium (Hf), vanadium (V), cobalt (Co), molybdenum (Mo), tungsten (W), aluminum (Al), gallium (Ga), silicon (Si), germanium (Ge), phosphorus (P), arsenic (As), yttrium (Y), lanthanum (La), cerium (Ce), lutetium (Lu), or combinations thereof. The additional metals can be as alternatives to or in addition to the Sn, Sb, Bi, In, and/or Te.

The particular metal used may significantly influence the absorption of radiation. Therefore, the metal component can be selected based on the desired radiation and absorption cross section. Tin, antimony, bismuth, tellurium, and indium provide strong absorption of extreme ultraviolet light at 13.5 nm. Hafnium provides good absorption of electron beam and extreme UV radiation. Metal compositions including titanium, vanadium, molybdenum, or tungsten have strong absorption at longer wavelengths, to provide, for example, sensitivity to 248 nm wavelength ultraviolet light.

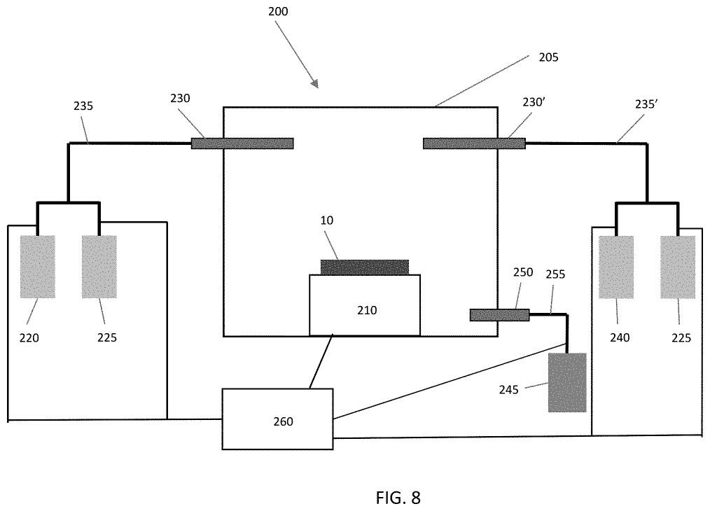

FIG. 9 shows a reaction the photoresist composition components undergo as a result of exposure to actinic radiation and heating according to an embodiment of the disclosure. FIG. 9 shows an exemplary chemical structure of the photoresist layer at various stages of the photoresist patterning method according to embodiments of the disclosure. As shown in FIG. 9, the photoresist composition includes an organometallic compound, for example SnX₂R₂, and a second compound, for example ammonia (NH₃). When the organometallic compound and the ammonia are combined, the organometallic compound reacts with some of the ammonia in the vapor phase to form a reaction product with amine groups attached to the metal (Sn) of the organometallic compound. The amine groups in the as deposited photoresist layer have hydrogen bonds that can substantially increase the boiling point of the deposited photoresist layer and help prevent the outgassing of metal-containing photoresist material. Moreover, the hydrogen bonds of the amine groups can help control the effect moisture has on photoresist layer quality.

When subsequently exposed to extreme ultraviolet radiation, the organometallic compound absorbs the extreme ultraviolet radiation and one or more organic R groups are cleaved from the organometallic compound to form an amino metallic compound in the radiation exposed areas. Then, when the post-exposure bake (PEB) performed, the amino metallic compounds crosslink through the amine groups in some embodiments, as shown in FIG. 9. In some embodiments, partial crosslinking of the amino metallic compounds occurs as a result of the exposure to extreme ultraviolet radiation.

In some embodiments of the disclosure, the developer composition, includes: a first solvent having Hansen solubility parameters of 18>δ_{d}>3, 7>δₚ>1, and 7>δₕ>1; an organic acid having an acid dissociation constant, pKa, of −11<pKa<4; and a Lewis acid, wherein the organic acid and the Lewis acid are different.

The units of the Hansen solubility parameters are (Joules/cm³)^{1/2} or, equivalently, MPa^{1/2} and are based on the idea that one molecule is defined as being like another if it bonds to itself in a similar way. Sa is the energy from dispersion forces between molecules. δₚ is the energy from dipolar intermolecular force between the molecules. δₕ is the energy from hydrogen bonds between molecules. The three parameters, δ_{d}, δₚ, and δₕ, can be considered as coordinates for a point in three dimensions, known as the Hansen space. The nearer two molecules are in Hansen space, the more likely they are to dissolve into each other.

In some embodiments, the concentration of the first solvent ranges from about 60 wt. % to about 99 wt. % based on a total weight of the developer composition. In some embodiments, the concentration of the first solvent is greater than 60 wt. %. In other embodiments, the concentration of the concentration of the first solvent ranges from about 70 wt. % to about 90 wt. % based on a total weight of the developer composition. In some embodiments, the first solvent is one or more of n-butyl acetate, methyl n-amyl ketone, hexane, heptane, and amyl acetate.

The acid dissociation constant, pKₐ, is the logarithmic constant of the acid dissociation constant Kₐ. Kₐ is a quantitative measure of the strength of an acid in solution. Kₐ is the equilibrium constant for the dissociation of a generic acid according to the equation HA+H₂O ↔A⁻+H₃O⁺, where HA dissociates into its conjugate base, A⁻, and a hydrogen ion which combines with a water molecule to form a hydronium ion. The dissociation constant can be expressed as a ratio of the equilibrium concentrations:

$${K}_{a} = \frac{[ {A}^{\text{-}} ] [ {H}_{3} {O}^{+} ]}{[ HA ] [ {H}_{2} O ]} .$$

In most cases, the amount of water is constant and the equation can be simplified to HA↔A⁻+H⁺, and

$${K}_{a} = \frac{[ {A}^{\text{-}} ] [ {H}^{+} ]}{[ HA ]} .$$

The logarithmic constant, pKₐ is related to Kₐ by the equation pKₐ=−log₁₀(Kₐ). The lower the value of pKₐ the stronger the acid. Conversely, the higher the value of pKₐ the stronger the base. In some embodiments, the organic acid is one or more of ethanedioic acid, methanoic acid, 2-hydroxypropanoic acid, 2-hydroxybutanedioic acid, citric acid, uric acid, trifluoromethanesulfonic acid, benzenesulfonic acid, ethanesulfonic acid, methanesulfonic acid, oxalic acid, and maleic acid. In an embodiment, the concentration of the organic acid is about 0.001 wt. % to about 30 wt. % based on a total weight of the developer composition.

In some embodiments, the Lewis acid includes one or more ions selected from Li⁺, Na⁺, K⁺, Be²⁺, Mg²⁺, Ca²⁺, Sr²⁺, Sn²⁺, Al³⁺, Se³⁺, Ca³⁺, In³⁺, La³⁺, Cr³⁺, Co³⁺, Fe³⁺, As³⁺, Ir³⁺, Sc³⁺, Y³⁺, Yb³⁺, Ln³⁺ Si⁴⁺, Ti⁴⁺, Zr⁴⁺, Th⁴⁺, Pu⁴⁺, VO²⁺, UO₂²⁺, (CH₃)₂Sn²⁺, RPO²⁺, ROPO²⁺, RSO²⁺, ROSO²⁺, SO₃²⁻, I₇⁻, I₅⁻, CI₅⁻, R₃C⁺, RCO⁺, NC⁺, Fe²⁺, CO²⁺, Ni²⁺, Cu²⁺, Zn²⁺, NO⁺, Cu+, Ag+, Au+, Tl⁺, Hg⁺, Cs⁺, Pd²⁺, Cd²⁺, Pt²⁺, CH₃Hg²⁺, Tl³⁺, Tl(CH₃)³⁺, RH³⁺, RS⁺, RSe⁺, RTe⁺, I⁻, Br⁻, OH⁻, RO²⁺, and I⁻, where Ln is a lanthanide, including La, Ce, Pr, Nd, Sm, Eu, Gd, Tb, Dy, Ho, Er, Tm, Yb, or Lu, and where R is a C1-C4 alkyl group.

In some embodiments, the Lewis acid is an ionic compound. In some embodiments, the Lewis acid contains one or more halogens. In some embodiments, the Lewis acid includes one or one or more compounds selected from I₂, Br₂, SO₂, Be(CH₃)₂, BF₃, BCl₃, BBr₃, B(OR)₃, Al(CH₃)₃, Ga(CH₃)₃, In(CH₃)₃, and B(CH₃)₃, where R is a C1-C4 alkyl group.

In some embodiments, the Lewis acid includes one or more of Sc(CF₃SO₃)₃, Y(CF₃SO₃)₃, and Ln(CF₃SO₃)₃, where Ln is La, Ce, Pr, Nd, Sm, Eu, Gd, Tb, Dy, Ho, Er, Tm, Yb, or Lu.

In some embodiments, the concentration of the Lewis acid is about 0.1 wt. % to about 15 wt. % based on a total weight of the developer composition, and in other embodiments, the concentration of the Lewis acid is about 1 wt. % to about 5 wt. % based on a total weight of the developer composition.

In some embodiments, the developer composition includes a second solvent having Hansen solubility parameters of 25>δ_{d}>13, 25>δₚ>3, and 30>δₕ>⁴, and the first solvent and the second solvent are different solvents. In some embodiments, the concentration of the second solvent ranges from about 0.1 wt. % to less than about 40 wt. % based on a total weight of the developer composition. In some embodiments, the second solvent is one or more of propylene glycol methyl ether, propylene glycol ethyl ether, γ-butyrolactone, cyclohexanone, ethyl lactate, methanol, ethanol, propanol, n-butanol, acetone, dimethyl formamide, acetonitrile, isopropanol, tetrahydrofuran, or acetic acid.

In some embodiments, the developer composition includes about 0.001 wt. % to about 30 wt. % of a chelate based on the total weight of the developer composition. In other embodiments, the developer composition includes about 0.1 wt. % to about 20 wt. % of the chelate based on the total weight of the developer composition. In some embodiments, the chelate is one or more of ethylenediaminetetraacetic acid (EDTA), ethylenediamine-N,N′-disuccinic acid (EDDS), diethylenetriaminepentaacetic acid (DTPA), polyaspartic acid, trans-1,2-cyclohexanediamine-N,N,N′,N′-tetraacetic acid monohydrate, ethylenediamine, or the like.

In some embodiments, the developer composition includes water or ethylene glycol at a concentration of about 0.001 wt. % to about 30 wt. % based on a total weight of the developer composition.

In some embodiments, the photoresist developer composition includes a surfactant in a concentration range of from about 0.001 wt. % to about less than 5 wt. % based on a total weight of the developer composition to increase the solubility and reduce the surface tension on the substrate. In other embodiments, the concentration of the surfactant ranges from about 0.01 wt. % to about 1 wt. % based on the total weight of the developer composition. In some embodiments, the surfactant is selected from the group consisting of alkylbenzenesulfonates, lignin sulfonates, fatty alcohol ethoxylates, and alkylphenol ethoxylates. In some embodiments, the surfactant is selected from the group consisting of sodium stearate, 4-(5-dodecyl) benzenesulfonate, ammonium lauryl sulfate, sodium lauryl sulfate, sodium laureth sulfate, sodium myreth sulfate, dioctyl sodium sulfosuccinate, perfluorooctanesulfonate, perfluorobutanesulfonate, alkyl-aryl ether phosphate, alkyl ether phosphates, sodium lauroyl sarcosinate, perfluoronononanoate, perfluorooctanoate, octenidine dihydrochloride, cetrimonium bromide, cetylpyridinium chloride, benzalkonium chloride, benzethonium chloride, dimethyldioctadecylammonium chloride, dioctadecyldimethylammonium bromide, 3-[(3-cholamidopropyl)dimethylammonio]-1-propanesulfonate, cocamidopropyl hydroxysultaine, cocamidopropyl betaine, phospholipidsphosphatidylserine, phosphatidylethanolamine, phosphatidylcholine, sphingomyelins, octaethylene glycol monodecyl ether, pentaethylene glycol monodecyl ether, polyethoxylated tallow amine, cocamide monoethanolamine, cocamide diethanolamine, glycerol monostearate, glycerol monolaurate, sorbitan monolaurate, sorbitan monostearate, sorbitan tristearate, and combinations thereof.

At concentrations of the developer composition components outsided the disclosed ranges, developer composition performance and development efficiency may be reduced, leading to increased photoresist residue and scum in the photoresist pattern, and increased line width roughness and line edge roughness.

In some embodiments, the developer 57 is applied to the photoresist layer 15 using a spin-on process. In the spin-on process, the developer 57 is applied to the photoresist layer 15 from above the photoresist layer 15 while the photoresist coated substrate is rotated, as shown in FIG. 4. In some embodiments, the developer 57 is supplied at a rate of between about 5 ml/min and about 800 ml/min, while the photoresist coated substrate 10 is rotated at a speed of between about 100 rpm and about 2000 rpm. In some embodiments, the developer is at a temperature of between about 20° C. and about 75° C. during the development operation. The development operation continues for between about 10 seconds to about 10 minutes in some embodiments.

While the spin-on operation is one suitable method for developing the photoresist layer 15 after exposure, it is intended to be illustrative and is not intended to limit the embodiment. Rather, any suitable development operations, including dip processes, puddle processes, and spray-on methods, may alternatively be used. All such development operations are included within the scope of the embodiments.

During the development process, the developer composition 57 dissolves the photoresist regions 52 not exposed to radiation (i.e.—not crosslinked), exposing the surface of the substrate 10, as shown in FIG. 5, and leaving behind well-defined exposed photoresist regions 50, having improved definition than provided by conventional negative tone photoresist photolithography.

After the developing operation S150, remaining developer is removed from the patterned photoresist covered substrate. The remaining developer is removed using a spin-dry process in some embodiments, although any suitable removal technique may be used. After the photoresist layer 15 is developed, and the remaining developer is removed, additional processing is performed while the patterned photoresist layer 50 is in place. For example, an etching operation, using dry or wet etching, is performed in some embodiments, to transfer the pattern of the photoresist layer 50 to the underlying substrate 10, forming recesses 55′ as shown in FIG. 6. The substrate 10 has a different etch resistance than the photoresist layer 15. In some embodiments, the etchant is more selective to the substrate 10 than the photoresist layer 15.

In some embodiments, the substrate 10 and the photoresist layer 15 contain at least one etching resistance molecule. In some embodiments, the etching resistant molecule includes a molecule having a low Onishi number structure, a double bond, a triple bond, silicon, silicon nitride, titanium, titanium nitride, aluminum, aluminum oxide, silicon oxynitride, combinations thereof, or the like.

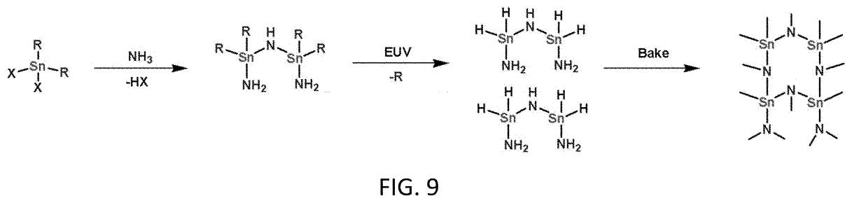

As shown in FIG. 10, in some embodiments, the Lewis acid in the developer composition interacts with an oxygen atom linking two metallic cores of a crosslinked organometallic photoresist. A nucleophile in the developer composition can then more easily cleave the crosslinked M-O-M bond thereby increasing the solubility of the photoresist in the developer composition and improving the efficiency of the development operation. In some embodiments, the nucleophile is generated by the Lewis acid. In other embodiments, a nucleophile is added to the developer composition. In some embodiments, the nucleophile is a polar material, including water, and chloride and bromide compounds. In some embodiments, the nucleophile is ammonium chloride or ammonium bromide. In some embodiments, the concentration of the nucleophile ranges from about 0.1 wt. % to about 15 wt. % based on the total weight of the developer composition.

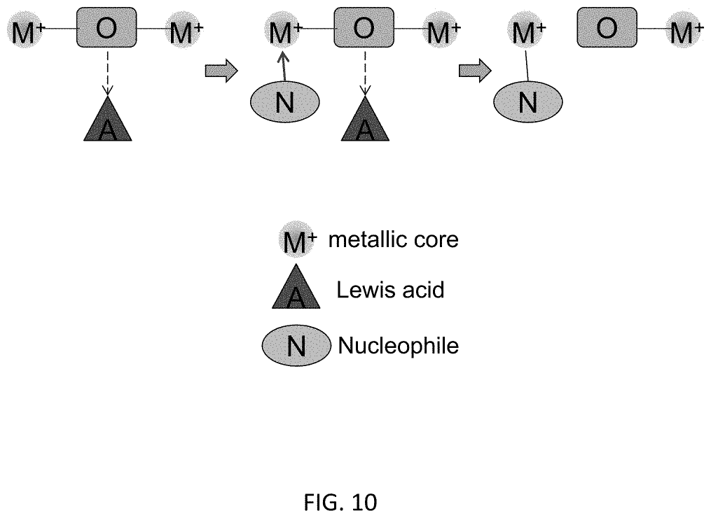

In some embodiments, a target layer 60 to be patterned is disposed over the substrate prior to forming the photoresist layer, as shown in FIG. 11. In some embodiments, the target layer 60 is a metallization layer or a dielectric layer, such as a passivation layer, disposed over a metallization layer. In embodiments where the target layer 60 is a metallization layer, the target layer 60 is formed of a conductive material using metallization processes, and metal deposition techniques, including chemical vapor deposition, atomic layer deposition, and physical vapor deposition (sputtering). Likewise, if the target layer 60 a dielectric layer, the target layer 60 is formed by dielectric layer formation techniques, including thermal oxidation, chemical vapor deposition, atomic layer deposition, and physical vapor deposition.

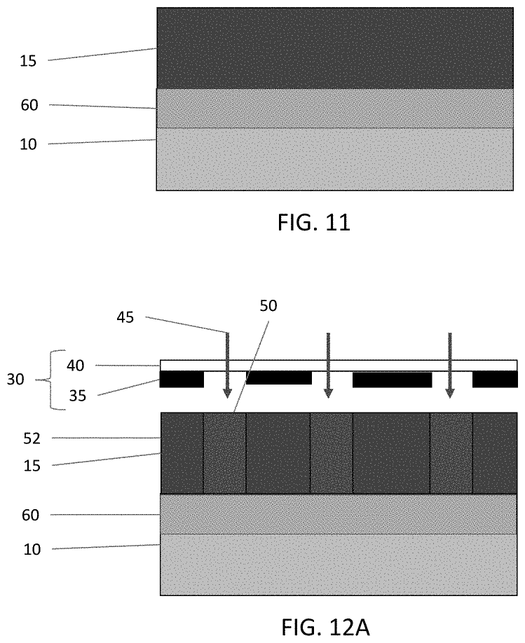

The photoresist layer 15 is subsequently selectively exposed to actinic radiation 45/97 to form exposed regions 50 and unexposed regions 52 in the photoresist layer, as shown in FIGS. 12A and 12B, and described herein in relation to FIGS. 3A and 3B. As explained herein, the photoresist is a negative photoresist, wherein polymer crosslinking occurs in the exposed regions 50 in some embodiments.

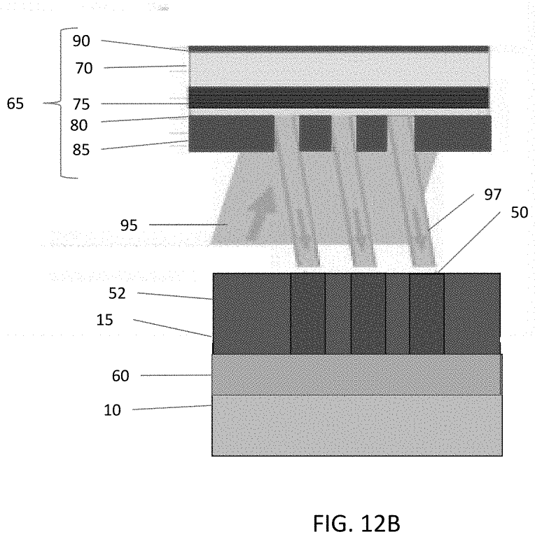

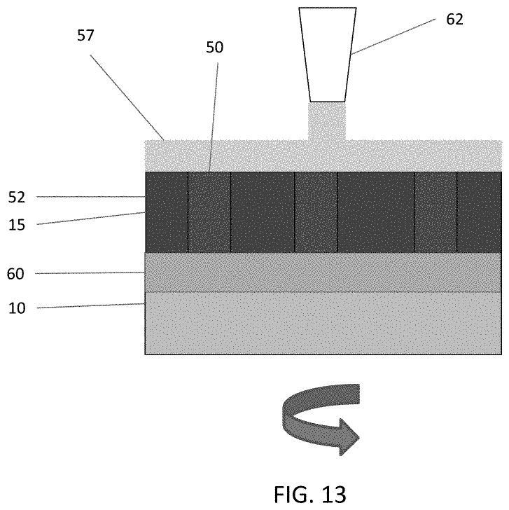

As shown in FIG. 13, the unexposed photoresist regions 52 are developed by dispensing developer 57 from a dispenser 62 to form a pattern of photoresist openings 55, as shown in FIG. 14. The development operation is similar to that explained with reference to FIGS. 4 and 5, herein.

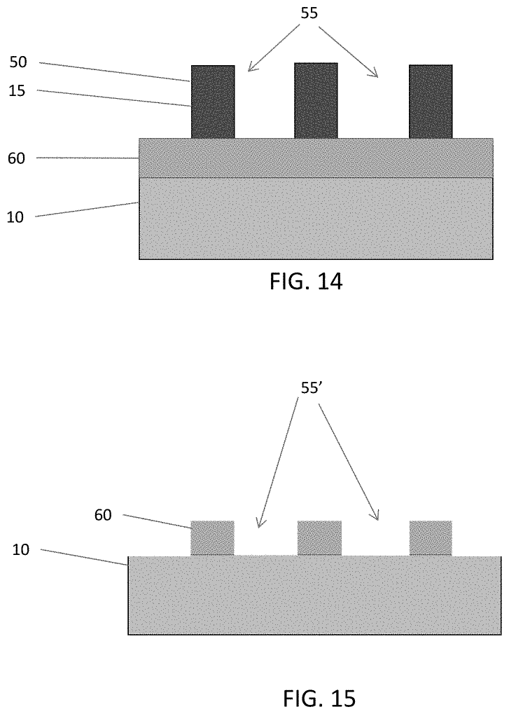

Then as shown in FIG. 15, the pattern 55 in the photoresist layer 15 is transferred to the target layer 60 using an etching operation and the photoresist layer is removed, as explained with reference to FIG. 6 to form pattern 55″ in the target layer 60.

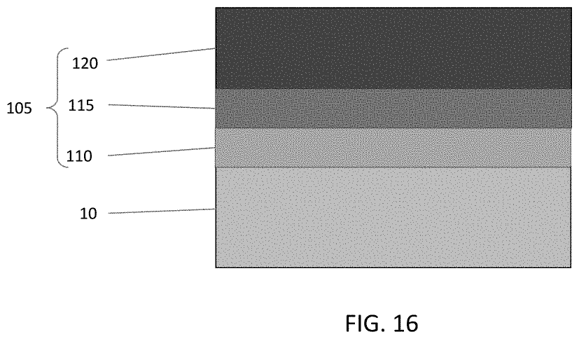

FIGS. 16-19 are cross sectional views of an alternative embodiment of manufacturing a semiconductor device according to the disclosure. In some embodiments, the resist layer 105 is a tri-layer resist including a bottom layer 110 disposed over the substrate 10 or a target layer. A middle layer 115 is disposed over the bottom layer 110, and a photoresist layer 120 is disposed over the middle layer 115, as shown in FIG. 16.

In some embodiments, the bottom layer 110 is an organic material having a substantially planar upper surface, and the middle layer 115 is an anti-reflective layer. In some embodiments, the organic material of the bottom layer 110 includes a plurality of monomers or polymers that are not cross-linked. In some embodiments, the bottom layer 110 contains a material that is patternable and/or has a composition tuned to provide anti-reflection properties. Exemplary materials for the bottom layer 110 include carbon backbone polymers. The bottom layer 110 is used to planarize the structure, as the underlying structure may be uneven depending on the structure of devices in an underlying device layer. In some embodiments, the bottom layer 110 is formed by a spin coating process. In certain embodiments, the thickness of the bottom layer 110 ranges from about 50 nm to about 500 nm.

The middle layer 115 of the tri-layer resist structure may have a composition that provides anti-reflective properties for the photolithography operation and/or hard mask properties. In some embodiments, the middle layer 115 includes a silicon-containing layer (e.g., a silicon hard mask material). The middle layer 115 may include a silicon-containing inorganic polymer. In other embodiments, the middle layer 115 includes a siloxane polymer. In other embodiments, the middle layer 115 includes silicon oxide (e.g., spin-on glass (SOG)), silicon nitride, silicon oxynitride, polycrystalline silicon, a metal-containing organic polymer material that contains metal such as titanium, titanium nitride, aluminum, and/or tantalum; and/or other suitable materials. The middle layer 115 may be bonded to adjacent layers, such as by covalent bonding, hydrogen bonding, or hydrophilic-to-hydrophilic forces.

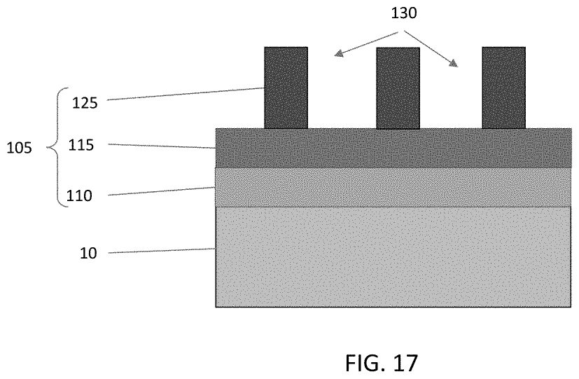

The photoresist layer 120 may be composed of any the photoresist compositions disclosed herein with respect to the photoresist layer 15 in FIG. 2. The photoresist layer 120 is photolithographically patterned to provide a pattern including exposed regions 125 of the photoresist layer and openings 130, as shown in FIG. 17. The photoresist layer is patternwise exposed to actinic radiation and developed according to the patterning operations disclosed herein with reference to FIGS. 3A, 3B, and 4 in some embodiments.

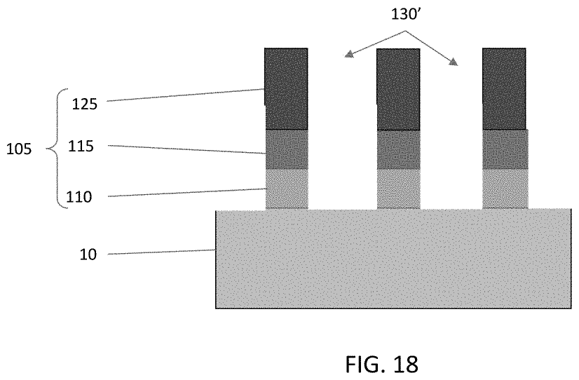

The pattern 130′ is extended into the middle layer 115 and bottom layer 110, as shown in FIG. 18, in some embodiments. The middle layer 115 and bottom layer 110 are etched using the photoresist layer 125 as an etch mask. The middle layer 115 and bottom layer 110 may be etched by wet or dry etching depending on the materials to be etched and the desired configuration of the pattern 130′.

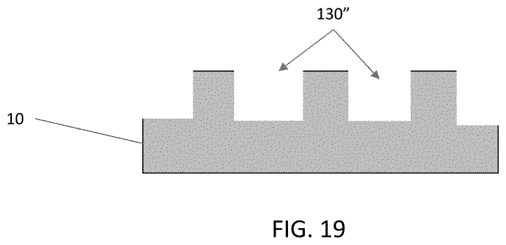

The pattern in the tri-layer resist 105 is then extended into the substrate 10 or a target layer and the remaining photoresist layer 120, middle layer 115, and bottom layer are removed, as shown in FIG. 19. The pattern is extended into the substrate 10 or a target layer using a suitable etching operation. The etchant used in the etching operation is selective to the substrate or target layer in some embodiments. The photoresist layer 120 may be removed by a suitable photoresist stripping or photoresist ashing operation in some embodiments. In some embodiments, the middle layer 115, and bottom layer 110 are removed during the photoresist stripping, photoresist ashing, or substrate etching operation. In some embodiments, different etching operations using different etchants are performed to remove each of the middle layer 115 and the bottom layer 110, and to etch the substrate 10 or target layer.

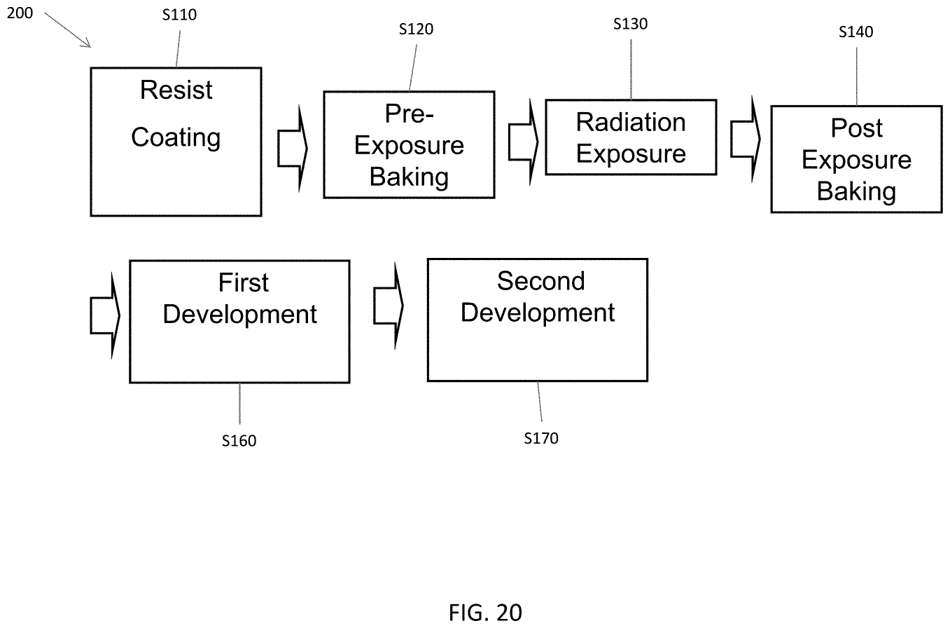

FIG. 20 illustrates a process flow 200 of manufacturing a semiconductor device according to embodiments of the disclosure. A resist is coated on a surface of a layer to be patterned or a substrate 10 in operation S110 and the resist undergoes a pre-exposure baking operation S120, as disclosed herein with reference to FIG. 1. The resist can be any of the resists disclosed herein. The resist layer 15 is selectively exposed to actinic radiation, as disclosed herein with reference to FIGS. 1, 3A, and 3B in operation S130. Then the selectively exposed resist layer undergoes a post-exposure baking operation S140, as disclosed herein with reference to FIG. 1. The resist layer is then developed in two successive operations S160 and S170 in some embodiments. In some embodiments, the first development operation S160 is performed using any of the Lewis acid-containing developer compositions disclosed herein. Then the selectively exposed resist layer is further developed in a second development operation S170 using a different developer composition from the Lewis acid-containing developer composition.

In some embodiments, the different developer composition includes an organic solvent or an aqueous solvent. In some embodiments, the organic solvent is one or more of n-butyl acetate, methyl n-amyl ketone, hexane, heptane, and amyl acetate. In some embodiments, the aqueous solvent is a basic solvent, such as tetramethyl ammonium hydroxide solution. In other embodiments, the first development operation S160 is performed using the different developer composition, and the second development operation S170 is performed using the Lewis acid-containing developer. In some embodiments, the different developer composition does not contain a Lewis acid.

Other embodiments include other operations before, during, or after the operations described above. In some embodiments, the disclosed methods include forming fin field effect transistor (FinFET) structures. In some embodiments, a plurality of active fins are formed on the semiconductor substrate. Such embodiments, further include etching the substrate through the openings of a patterned hard mask to form trenches in the substrate; filling the trenches with a dielectric material; performing a chemical mechanical polishing (CMP) process to form shallow trench isolation (STI) features; and epitaxy growing or recessing the STI features to form fin-like active regions. In some embodiments, one or more gate electrodes are formed on the substrate. Some embodiments include forming gate spacers, doped source/drain regions, contacts for gate/source/drain features, etc. In other embodiments, a target pattern is formed as metal lines in a multilayer interconnection structure. For example, the metal lines may be formed in an inter-layer dielectric (ILD) layer of the substrate, which has been etched to form a plurality of trenches. The trenches may be filled with a conductive material, such as a metal; and the conductive material may be polished using a process such as chemical mechanical planarization (CMP) to expose the patterned ILD layer, thereby forming the metal lines in the ILD layer. The above are non-limiting examples of devices/structures that can be made and/or improved using the method described herein.

In some embodiments, active components such diodes, field-effect transistors (FETs), metal-oxide semiconductor field effect transistors (MOSFET), complementary metal-oxide semiconductor (CMOS) transistors, bipolar transistors, high voltage transistors, high frequency transistors, FinFETs, other three-dimensional (3D) FETs, metal-oxide semiconductor field effect transistors (MOSFET), complementary metal-oxide semiconductor (CMOS) transistors, bipolar transistors, high voltage transistors, high frequency transistors, other memory cells, and combinations thereof are formed, according to embodiments of the disclosure.

The novel photoresist developer compositions and negative photoresist photolithography techniques according to the present disclosure provide higher semiconductor device feature density with reduced defects in a higher efficiency process than conventional developers and techniques. The novel photoresist developer compositions and negative photoresist photolithography techniques according to the present disclosure provide improved removal of residue and scum from the developed photoresist pattern. Developer compositions and developing operations according to the present disclosure provide up to a 19% improvement in development efficiency compared to other developer compositions and developing operations, resulting in a significant reduction in photoresist scum remaining in the developed photoresist pattern.

An embodiment of the disclosure is a method of manufacturing a semiconductor device, including forming a photoresist layer over a substrate and selectively exposing the photoresist layer to actinic radiation to form a latent pattern. The latent pattern is developed by applying a developer composition to the selectively exposed photoresist layer to form a pattern in the photoresist layer. The developer composition includes: a first solvent having Hansen solubility parameters of 18>δ_{d}>³, 7>δₚ>1, and 7>δₕ>1; an organic acid having an acid dissociation constant, pKa, of −11<pKa<4; and a Lewis acid, wherein the organic acid and the Lewis acid are different. In an embodiment, the developer composition includes a second solvent having Hansen solubility parameters of 25>δ_{d}>13, 25>δₚ>3, and 30>δₕ>⁴, and the first solvent and the second solvent are different solvents. In an embodiment, the developer composition further comprises 0.1 wt. % to 20 wt. % of a chelate based on a total weight of the developer composition. In an embodiment, the Lewis acid includes one or more ions selected from selected from the group consisting of Li⁺, Na⁺, K⁺, Be²⁺, Mg²⁺, Ca²⁺, Sr²⁺, Sn²⁺, Al³⁺, Se³⁺, Ca³⁺, In³⁺, La³⁺, Cr³⁺, Co³⁺, Fe³⁺, As³⁺, Ir³⁺, Sc³⁺, Y³⁺, Yb³⁺, Ln³⁺ Si⁴⁺, Ti⁴⁺, Zr⁴⁺, Th⁴⁺, Pu⁴⁺, VO²⁺, UO₂²⁺, (CH₃)₂Sn²⁺, RPO²⁺, ROPO²⁺, RSO²⁺, ROSO²⁺, SO₃²⁻, I₇⁻, I₅⁻, CI₅⁻, R₃C⁺, RCO⁺, NC⁺, Fe²⁺, Co²⁺, Ni²⁺, Cu²⁺, Zn²⁺, NO⁺, Cu⁺, Ag⁺, Au⁺, Tl⁺, Hg⁺, Cs⁺, Pd²⁺, Cd²⁺, Pt²⁺, CH₃Hg²⁺, Tl³⁺, Tl(CH₃)³⁺, RH³⁺, RS⁺, RSe⁺, RTe⁺, I⁻, Br⁻, OH⁻, RO²⁺, and I⁻, or one or more compounds selected from selected from the group consisting of I₂, Br₂, SO₂, Be(CH₃)₂, BF₃, BCl₃, BBr₃, B(OR)₃, Al(CH₃)₃, Ga(CH₃)₃, In(CH₃)₃, and B(CH₃)₃, where R is a C1-C4 alkyl group. In an embodiment, the Lewis acid includes one or more selected from the group consisting of Sc(CF₃SO₃)₃, Y(CF₃SO₃)₃, and Ln(CF₃SO₃)₃, where Ln is La, Ce, Pr, Nd, Sm, Eu, Gd, Tb, Dy, Ho, Er, Tm, Yb, or Lu. In an embodiment, a concentration of the Lewis acid is 0.1 wt. % to 15 wt. % based on a total weight of the developer composition. In an embodiment, a concentration of the first solvent ranges from greater than 60 wt. % to 99 wt. % based on a total weight of the developer composition. In an embodiment, a concentration of the organic acid is 0.001 wt. % to 30 wt. % based on a total weight of the developer composition In an embodiment, the developer composition includes water or ethylene glycol at a concentration of 0.001 wt. % to 30 wt. % based on a total weight of the developer composition. In an embodiment, the method includes extending the pattern in the photoresist layer into the substrate. In an embodiment, the latent pattern is developed in a first and second successive development operations, wherein the first and second development operations use different developer composition. In an embodiment, a developer composition used in the first development operation does not contain the Lewis acid. In an embodiment, a developer composition used in the second development operation does not contain the Lewis acid.

Another embodiment is a method, including forming a resist layer over a substrate, and patternwise crosslinking the resist layer to form a latent pattern in the resist layer including a crosslinked portion and an uncrosslinked portion of the resist layer. The latent pattern is developed by applying a developer composition to remove the uncrosslinked portion of the resist layer to form a pattern of the crosslinked portion of the resist layer. The developer composition includes: a first solvent having Hansen solubility parameters of 18>δ_{d}>3, 7>δₚ>1, and 7>δₕ>1; an organic acid having an acid dissociation constant, pKa, of −11<pKa<4; and a Lewis acid, wherein the organic acid and the Lewis acid are different. In an embodiment, the developer composition includes a second solvent having Hansen solubility parameters of 25>δ_{d}>13, 25>δₚ>3, and 30>δₕ>4, and the first solvent and the second solvent are different solvents. In an embodiment, the second solvent is one or more selected from the group consisting of of propylene glycol methyl ether, propylene glycol ethyl ether, γ-butyrolactone, cyclohexanone, ethyl lactate, methanol, ethanol, propanol, n-butanol, acetone, dimethyl formamide, acetonitrile, isopropanol, tetrahydrofuran, and acetic acid. In an embodiment, the first solvent is one or more selected from the group consisting of n-butyl acetate, methyl n-amyl ketone, hexane, heptane, and amyl acetate. In an embodiment, the organic acid is one or more selected from the group consisting of ethanedioic acid, methanoic acid, 2-hydroxypropanoic acid, 2-hydroxybutanedioic acid, citric acid, uric acid, trifluoromethanesulfonic acid, benzenesulfonic acid, ethanesulfonic acid, methanesulfonic acid, oxalic acid, and maleic acid. In an embodiment, the Lewis acid is one or more selected from the group consisting of Sc(CF₃SO₃)₃, Y(CF₃SO₃)₃, and Ln(CF₃SO₃)₃, where Ln is La, Ce, Pr, Nd, Sm, Eu, Gd, Tb, Dy, Ho, Er, Tm, Yb, or Lu. In an embodiment, the latent pattern is developed in a first and second successive development operations, wherein the first and second development operations use different developer composition. In an embodiment, a developer composition used in the first development operation does not contain the Lewis acid. In an embodiment, a developer composition used in the second development operation does not contain the Lewis acid.

Another embodiment of the disclosure is a developer composition, including: a first solvent having Hansen solubility parameters of 18>δ_{d}>3, 7>δₚ>1, and 7>δₕ>1; an organic acid having an acid dissociation constant, pKa, of −11<pKa<4; and a Lewis acid, wherein the organic acid and the Lewis acid are different. In an embodiment, the developer composition includes a second solvent having Hansen solubility parameters of 25>δ_{d}>13, 25>δₚ>3, and 30>δₕ>4, and the first solvent and the second solvent are different solvents. In an embodiment, the Lewis acid includes one or more ions selected from selected from the group consisting of Li⁺, Na⁺, K⁺, Be²⁺, Mg²⁺, Ca²⁺, Sr²⁺, Sn²⁺, Al³⁺, Se³⁺, Ca³, In³⁺, La³⁺, Cr³⁺, Co³⁺, Fe³⁺, As³⁺, Ir³⁺, Sc³⁺, Y³⁺, Yb³⁺, Ln³⁺ Si⁴⁺, Ti⁴⁺, Zr⁴⁺, Th⁴⁺, Pu⁴⁺, VO²⁺, UO₂²⁺, (CH₃)₂Sn²⁺, RPO²⁺, ROPO²⁺, RSO²⁺, ROSO²⁺, SO₃²⁻, I₇⁻, I₅⁻, CI₅⁻, R₃C⁺, RCO⁺, NC⁺, Fe²⁺, Co²⁺, Ni²⁺, Cu²⁺, Zn²⁺, NO⁺, Cu⁺, Ag⁺, Au⁺, Tl⁺, Hg⁺, Cs⁺, Pd²⁺, Cd²⁺, Pt²⁺, CH₃Hg²⁺, Tl³⁺, Tl(CH₃)³⁺, RH³⁺, RS⁺, RSe⁺, RTe⁺, I⁻, Br⁻, OH⁻, RO²⁺, and I⁻, or one or more compounds selected from the group consisting of I₂, Br₂, SO₂, Be(CH₃)₂, BF₃, BCl₃, BBr₃, B(OR)₃, Al(CH₃)₃, Ga(CH₃)₃, In(CH₃)₃, and B(CH₃)₃, where R is a C1-C4 alkyl group. In an embodiment, the Lewis acid includes one or more selected from the group consisting of Sc(CF₃SO₃)₃, Y(CF₃SO₃)₃, and Ln(CF₃SO₃)₃, where Ln is La, Ce, Pr, Nd, Sm, Eu, Gd, Tb, Dy, Ho, Er, Tm, Yb, or Lu. In an embodiment, the Lewis acid contains one or more halogens. In an embodiment, the Lewis acid is an ionic compound. In an embodiment, the developer composition includes 0.1 wt. % to 20 wt. % of a chelate based on a total weight of the developer composition. In an embodiment, a concentration of the Lewis acid is 0.1 wt. % to 15 wt. % based on a total weight of the developer composition. In an embodiment, a concentration of the first solvent ranges from greater than 60 wt. % to 99 wt. % based on a total weight of the developer composition. In an embodiment, a concentration of the organic acid is 0.001 wt. % to 30 wt. % based on a total weight of the developer composition. In an embodiment, the developer composition includes water or ethylene glycol at a concentration of 0.001 wt. % to 30 wt. % based on a total weight of the developer composition. In an embodiment, the developer composition includes 0.001 wt. % to 30 wt. % of a chelate based on a total weight of the developer composition. In an embodiment, the chelate is one or more selected from the group consisting of ethylenediaminetetraacetic acid (EDTA), ethylenediamine-N,N′-disuccinic acid (EDDS), diethylenetriaminepentaacetic acid (DTPA), polyaspartic acid, trans-1,2-cyclohexanediamine-N,N,N′,N′-tetraacetic acid monohydrate, and ethylenediamine.

Another embodiment of the disclosure is a method of manufacturing a semiconductor device including, forming a resist layer over a substrate and selectively exposing the resist layer to actinic radiation. The selectively exposed resist layer is developed by applying a developer composition to form a pattern in the resist layer. The developer composition includes: a first solvent having Hansen solubility parameters of 18>δ_{d}>3, 7>δₚ>1, and 7>δₕ>1; an organic acid having an acid dissociation constant, pKa, of −11<pKa<4; and a Lewis acid containing a halogen or an ionic Lewis acid, wherein the organic acid and the Lewis acid are different. In an embodiment, the resist layer is a tri-layer resist, including a bottom layer, a middle layer, and an upper photosensitive layer, and the bottom layer, middle layer, and upper photosensitive layer are formed of different materials. In an embodiment, the developer composition includes a second solvent having Hansen solubility parameters of 25>δ_{d}>13, 25>δₚ>3, and 30>δₕ>4, and the first solvent and the second solvent are different solvents. In an embodiment, the method includes forming a target layer over the substrate before forming the resist layer. In an embodiment, the method includes extending the pattern in the resist layer into the target layer. In an embodiment, the ionic Lewis acid includes one or more ions selected from the group consisting of Li⁺, Na⁺, K⁺, Be²⁺, Mg²⁺, Ca²⁺, Sr²⁺, Sn²⁺, Al³⁺, Se³⁺, Ca³⁺, In³⁺, La³⁺, Cr³⁺, Co³⁺, Fe³⁺, As³⁺, Ir³⁺, Sc³⁺, Y³⁺, Yb³⁺, Ln³⁺ Si⁴⁺, Ti⁴⁺, Zr⁴⁺, Th⁴⁺, Pu⁴⁺, VO²⁺, UO₂²⁺, (CH₃)₂Sn²⁺, RPO²⁺, ROPO²⁺, RSO²⁺, ROSO²⁺, SO₃²⁻, I₇⁻, I₅⁻, CI₅⁻, R₃C⁺, RCO⁺, NC⁺, Fe²⁺, CO²⁺, Ni²⁺, Cu²⁺, Zn²⁺, NO⁺, Cu⁺, Ag⁺, Au⁺, Tl⁺, Hg⁺, Cs⁺, Pd²⁺, Cd²⁺, Pt²⁺, CH₃Hg²⁺, Tl³⁺, Tl(CH₃)³⁺, RH³⁺, RS⁺, RSe⁺, RTe⁺, I⁻, Br⁻, OH⁻, RO²⁺, and I⁻, where R is a C1-C4 alkyl group. In an embodiment, the Lewis acid containing a halogen is one or more selected from the group consisting of 12, Br₂, BF₃, BCl₃, or BBr. In an embodiment, the Lewis acid includes one or more selected from the group consisting of Sc(CF₃SO₃)₃, Y(CF₃SO₃)₃, and Ln(CF₃SO₃)₃, where Ln is La, Ce, Pr, Nd, Sn, Eu, Cd, Tb, Dy, Ho, Er, Tm, Yb, or Lu. In an embodiment, a concentration of the Lewis acid is 0.1 wt. % to 15 wt. % based on a total weight of the developer composition. In an embodiment, a concentration of the first solvent ranges from greater than 60 wt. % to 99 wt. % based on a total weight of the developer composition. In an embodiment, a concentration of the organic acid is 0.001 wt. % to 30 wt % based on a total weight of the developer composition. In an embodiment, the developer composition further comprises water or ethylene glycol at a concentration of 0.001 wt. % to 30 wt. % based on a total weight of the developer composition. In an embodiment, the method includes heating the resist layer after selectively exposing the resist layer to actinic radiation and before developing the resist layer. In an embodiment, the developer composition is at a temperature of 25° C. to 75° C. during the developing. In an embodiment, the method includes heating the resist layer before selectively exposing the resist layer to actinic radiation. In an embodiment, the developer composition includes a surfactant. In an embodiment, a concentration of the surfactant is from 0.001 wt. % to 1 wt. % based on a total weight of the developer composition. In an embodiment, the selectively exposed resist layer is developed by a first and second successive development operations, wherein the first and second development operations use different developer composition. In an embodiment, a developer composition used in the first development operation does not contain the Lewis acid. In an embodiment, a developer composition used in the second development operation does not contain the Lewis acid.

Another embodiment of the disclosure is a method of patterning a photoresist layer, including forming a negative tone photoresist layer over a substrate. The photoresist layer is selectively exposed to actinic radiation to form a latent pattern. Portions of the photoresist layer not exposed to the actinic radiation are removed by applying a developer composition to the selectively exposed photoresist layer to form a pattern. The developer composition includes: a first solvent having Hansen solubility parameters of 18>δ_{d}>3, 7>δₚ>1, and 7>δₕ>1; an organic acid having an acid dissociation constant, pKa, of −11<pKa<4; and a Lewis acid containing a halogen or an ionic Lewis acid, wherein the organic acid and the Lewis acid are different. In an embodiment, the developer composition includes a second solvent having Hansen solubility parameters of 25>δ_{d}>13, 25>δₚ>3, and 30>δₕ>⁴, and the first solvent and the second solvent are different solvents. In an embodiment, a concentration of the second solvent ranges from 0.1 wt. % to less than 40 wt. % based on a total weight of the developer composition. In an embodiment, the second solvent is one or more selected from the group consisting of propylene glycol methyl ether, propylene glycol ethyl ether, γ-butyrolactone, cyclohexanone, ethyl lactate, methanol, ethanol, propanol, n-butanol, acetone, dimethyl formamide, acetonitrile, isopropanol, tetrahydrofuran, and acetic acid. In an embodiment, the first solvent is one or more selected from the group consisting of n-butyl acetate, methyl n-amyl ketone, hexane, heptane, and amyl acetate. In an embodiment, a concentration of the first solvent ranges from 60 wt. % to 99 wt. % based on a total weight of the developer composition. In an embodiment, the organic acid is one or more selected from the group consisting of ethanedioic acid, methanoic acid, 2-hydroxypropanoic acid, 2-hydroxybutanedioic acid, citric acid, uric acid, trifluoromethanesulfonic acid, benzenesulfonic acid, ethanesulfonic acid, methanesulfonic acid, oxalic acid, and maleic acid. In an embodiment, a concentration of the organic acid ranges from 0.001 wt. % to 20 wt. % based on a total weight of the developer composition. In an embodiment, the Lewis acid is one or more of Sc(CF₃SO₃)₃, Y(CF₃SO₃)₃, and Ln(CF₃SO₃)₃, where Ln is La, Ce, Pr, Nd, Sm, Eu, Gd, Tb, Dy, Ho, Er, Tm, Yb, or Lu. In an embodiment, the method includes heating the photoresist layer after selectively exposing the photoresist layer to actinic radiation and before removing portions of the photoresist layer. In an embodiment, the selectively exposing the photoresist layer and the heating the photoresist layer after selectively exposing the photoresist layer to actinic radiation crosslinks selectively exposed portions of the photoresist layer. In an embodiment, the developer composition is at a temperature of 25° C. to 75° C. during the developing. In an embodiment, the method includes heating the photoresist layer before selectively exposing the photoresist layer to actinic radiation.

Another embodiment of the disclosure is a composition, including: a first solvent having Hansen solubility parameters of 18>δ_{d}>³, 7>δₚ>1, and 7>δₕ>1; an organic acid having an acid dissociation constant, pKa, of −11<pKa<4; and a Lewis acid, wherein the organic acid and the Lewis acid are different. In an embodiment, the composition includes a second solvent having Hansen solubility parameters of 25>δ_{d}>13, 25>δₚ>3, and 30>δh>⁴, and the first solvent and the second solvent are different solvents. In an embodiment, the second solvent is one or more selected from the group consisting of propylene glycol methyl ether, propylene glycol ethyl ether, γ-butyrolactone, cyclohexanone, ethyl lactate, methanol, ethanol, propanol, n-butanol, acetone, dimethyl formamide, acetonitrile, isopropanol, tetrahydrofuran, and acetic acid. In an embodiment, a concentration of the second solvent ranges from 0.1 wt. % to less than 40 wt. % based on a total weight of the composition. In an embodiment, the first solvent is one or more selected from the group consisting of n-butyl acetate, methyl n-amyl ketone, hexane, heptane, and amyl acetate. In an embodiment, a concentration of the first solvent ranges from 60 wt. % to 99 wt. % based on a total weight of the composition. In an embodiment, the organic acid is one or more selected from the group consisting of ethanedioic acid, methanoic acid, 2-hydroxypropanoic acid, 2-hydroxybutanedioic acid, citric acid, uric acid, trifluoromethanesulfonic acid, benzenesulfonic acid, ethanesulfonic acid, methanesulfonic acid, oxalic acid, and maleic acid. In an embodiment, a concentration of the organic acid is 0.001 wt. % to 30 wt. % based on a total weight of the composition. In an embodiment, the composition includes water or ethylene glycol at a concentration of 0.001 wt. % to 30 wt. % based on a total weight of the composition. In an embodiment, the Lewis acid includes one or more ions selected from the group consisting of Li⁺, Na⁺, K⁺, Be²⁺, Mg²⁺, Ca²⁺, Sr²⁺, Sn²⁺, Al³⁺, Se³⁺, Ca³, In³⁺, La³⁺, Cr³⁺, Co³S, Fe³⁺, As³⁺, Ir³⁺, Sc³⁺, Y³⁺, Yb³⁺, Ln³⁺ Si⁴⁺, Ti⁴⁺, Zr⁴⁺, Th⁴⁺, Pu⁴⁺, VO²⁺, UO₂²⁺, (CH₃)₂Sn²⁺, RPO²⁺, ROPO²⁺, RSO²⁺, ROSO²⁺, SO₃²⁻, I₇⁻, I₅⁻, CI₅⁻, R₃C⁺, RCO⁺, NC⁺, Fe²⁺, CO²⁺, Ni²⁺, Cu²⁺, Zn²⁺, NO⁺, Cu⁺, Ag⁺, Au⁺, Tl⁺, Hg⁺, Cs⁺, Pd²⁺, Cd²⁺, Pt²⁺, CH₃Hg²⁺, Tl³⁺, Tl(CH₃)³⁺, RH³⁺, RS⁺, RSe⁺, RTe⁺, I⁻, Br⁻, OH, RO²⁺, and I⁻, or one or more compounds selected from the group consisting of I₂, Br₂, SO₂, Be(CH₃)₂, BF₃, BCl₃, BBr₃, B(OR)₃, Al(CH₃)₃, Ga(CH₃)₃, In(CH₃)₃, and B(CH₃)₃, where R is a C1-C4 alkyl group. In an embodiment, the Lewis acid includes one or more selected from the group consisting of Sc(CF₃SO₃)₃, Y(CF₃SO₃)₃, and Ln(CF₃SO₃)₃, where Ln is La. Ce, Pr, Nd, Sm, Eu, Gd, Tb, Dy, Ho, Er, Tm, Yb, or Lu. In an embodiment, the composition includes 0.1 wt. % to 20 wt. % of a chelate based on a total weight of the composition. In an embodiment, a concentration of the Lewis acid is 0.1 wt. % to 15 wt. % based on a total weight of the composition. In an embodiment, the composition includes 0.001 wt. % to 30 wt. % of a chelate based on a total weight of the composition. In an embodiment, the chelate is one or more selected from the group consisting of ethylenediaminetetraacetic acid (EDTA), ethylenediamine-N,N′-disuccinic acid (EDDS), diethylenetriaminepentaacetic acid (DTPA), polyaspartic acid, trans-1,2-cyclohexanediamine-N,N,N′,N′-tetraacetic acid monohydrate, and ethylenediamine. In an embodiment, the composition includes from 0.001 wt. % to 1 wt. % of a surfactant based on a total weight of the composition. In an embodiment, the surfactant is one or more selected from the group consisting of alkylbenzenesulfonates, lignin sulfonates, fatty alcohol ethoxylates, and alkylphenol ethoxylates. In an embodiment, the surfactant is one or more selected from the group consisting of sodium stearate, 4-(5-dodecyl) benzenesulfonate, ammonium lauryl sulfate, sodium lauryl sulfate, sodium laureth sulfate, sodium myreth sulfate, dioctyl sodium sulfosuccinate, perfluorooctanesulfonate, perfluorobutanesulfonate, alkyl-aryl ether phosphate, alkyl ether phosphates, sodium lauroyl sarcosinate, perfluoronononanoate, perfluorooctanoate, octenidine dihydrochloride, cetrimonium bromide, cetylpyridinium chloride, benzalkonium chloride, benzethonium chloride, dimethyldioctadecylammonium chloride, dioctadecyldimethylammonium bromide, 3-[(3-cholamidopropyl)dimethylammonio]-1-propanesulfonate, cocamidopropyl hydroxysultaine, cocamidopropyl betaine, phospholipidsphosphatidylserine, phosphatidylethanolamine, phosphatidylcholine, sphingomyelins, octaethylene glycol monodecyl ether, pentaethylene glycol monodecyl ether, polyethoxylated tallow amine, cocamide monoethanolamine, cocamide diethanolamine, glycerol monostearate, glycerol monolaurate, sorbitan monolaurate, sorbitan monostearate, and sorbitan tristearate.

Another embodiment of the disclosure is a photoresist developer composition including: a first solvent having Hansen solubility parameters of 18>δ_{d}>3, 7>δₚ>1, and 7>δₕ>1; an organic acid having an acid dissociation constant, pKa, of −11<pKa<4; and a Lewis acid containing a halogen or an ionic Lewis acid, wherein the organic acid and the Lewis acid are different. In an embodiment, the photoresist developer composition includes a second solvent having Hansen solubility parameters of 25>δ_{d}>13, 25>δₚ>3, and 30>δₕ>4, and the first solvent and the second solvent are different solvents. In an embodiment, the ionic Lewis acid includes one or more ions selected from the group consisting of Li⁺, Na⁺, K⁺, Be²⁺, Mg²⁺, Ca²⁺, Sr²⁺, Sn²⁺, Al³⁺, Se³⁺, Ca³, In³⁺, La³⁺, Cr³⁺, Co³, Fe³⁺, As³⁺, Ir³⁺, Sc³⁺, Y³⁺, Yb³⁺, Ln³⁺ Si⁴⁺, Ti⁴⁺, Zr⁴⁺, Th⁴⁺, Pu⁴⁺, VO²⁺, UO₂²⁺, (CH₃)₂Sn²⁺, RPO²⁺, ROPO²⁺, RSO²⁺, ROSO²⁺, SO₃²⁻, I₇⁻, I₅⁻, CI₅⁻, R₃C⁺, RCO⁺, NC⁺, Fe²⁺, Co²⁺, Ni²⁺, Cu²⁺, Zn²⁺, NO⁺, Cu⁺, Ag⁺, Au⁺, Tl⁺, Hg⁺, Cs⁺, Pd²⁺, Cd²⁺, Pt²⁺, CH₃Hg²⁺, Tl³⁺, Tl(CH₃)³⁺, RH³⁺, RS⁺, RSe⁺, RTe⁺, I⁻, Br⁻, OH⁻, RO²⁺, and I⁻, where R is a C1-C4 alkyl group. In an embodiment, the Lewis acid containing a halogen is one or more selected from the group consisting of I₂, Br₂, BF₃, BCl₃, or BBr. In an embodiment, the Lewis acid includes one or more selected from the group consisting of Sc(CF₃SO₃)₃, Y(CF₃SO₃)₃, and Ln(CF₃SO₃)₃, where Ln is La, Ce, Pr, Nd, Sm, Eu, Gd, Tb, Dy, Ho, Er, Im, Yb, or Lu. In an embodiment, a concentration of the Lewis acid is 0.1 wt. % to 15 wt. % based on a total weight of the photoresist developer composition. In an embodiment, a concentration of the first solvent ranges from greater than 60 wt. % to 99 wt % based on a total weight of the photoresist developer composition. In an embodiment, a concentration of the organic acid is 0.001 wt. % to 30 wt. % based on a total weight of the photoresist developer composition. In an embodiment, the photoresist developer composition includes water or ethylene glycol at a concentration of 0.001 wt. % to 30 wt. % based on a total weight of the photoresist developer composition. In an embodiment, the photoresist developer composition includes a surfactant. In an embodiment, a concentration of the surfactant is from 0.001 wt. % to 1 wt. % based on a total weight of the photoresist developer composition.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, comprising:
forming a photoresist layer over a substrate;
selectively exposing the photoresist layer to actinic radiation to form a latent pattern; and
developing the latent pattern by applying a developer composition to the selectively exposed photoresist layer to form a pattern in the photoresist layer,
wherein the developer composition comprises:
a first solvent having Hansen solubility parameters of 18>δ_{d}>3, 7>δₚ>1, and 7>δₕ>1;
an organic acid having an acid dissociation constant, pKa, of −11<pKa<4; and
a Lewis acid,
wherein the organic acid and the Lewis acid are different.

2. The method according to claim 1, wherein the developer composition further comprises a second solvent having Hansen solubility parameters of 25>δ_{d}>13, 25>δₚ>3, and 30>δₕ>⁴, and
wherein the first solvent and the second solvent are different solvents.

3. The method according to claim 1, wherein the developer composition further comprises 0.1 wt. % to 20 wt. % of a chelate based on a total weight of the developer composition.

4. The method according to claim 1, wherein the Lewis acid includes one or more ions selected from the group consisting of Li⁺, Na⁺, K⁺, Be²⁺, Mg²⁺, Ca²⁺, Sr²⁺, Sn²⁺, Al³⁺, Se³⁺, Ca³⁺, In³⁺, La³⁺, Cr³⁺, Co³⁺, Fe³⁺, As³⁺, I³⁺, Sc³⁺, Y³⁺, Yb³⁺, Ln³⁺ Si⁴⁺, Ti⁴⁺, Zr⁴⁺, Th⁴⁺, Pu⁴⁺, VO²⁺, UO₂²⁺, (CH₃)₂Sn²⁺, RPO²⁺, ROPO²⁺, RSO²⁺, ROSO²⁺, SO₃²⁻, I₇⁻, I₅⁻, CI₅⁻, R₃C⁺, RCO⁺, NC⁺, Fe²⁺, Co²⁺, Ni²⁺, Cu²⁺, Zn²⁺, NO⁺, Cu⁺, Ag⁺, Au⁺, Tl⁺, Hg⁺, Cs⁺, Pd²⁺, Cd²⁺, Pt²⁺, CH₃Hg²⁺, Tl³⁺, Tl(CH₃)³⁺, RH³⁺, RS⁺, RSe⁺, RTe⁺, I⁻, Br⁻, OH⁻, RO²⁺, and I⁻, or one or more compounds selected from the group consisting of I₂, Br₂, SO₂, Be(CH₃)₂, BF₃, BCl₃, BBr₃, B(OR)₃, Al(CH₃)₃, Ga(CH₃)₃, In(CH₃)₃, and B(CH₃)₃, where R is a C1-C4 alkyl group.

5. The method according to claim 4, wherein the Lewis acid includes one or more selected from the group consisting of Sc(CF₃SO₃)₃, Y(CF₃SO₃)₃, and Ln(CF₃SO₃)₃, where Ln is La, Ce, Pr, Nd, Sm, Eu, Gd, Tb, Dy, Ho, Er, Tm, Yb, and Lu.

6. The method according to claim 4, wherein a concentration of the Lewis acid is 0.1 wt. % to 15 wt. % based on a total weight of the developer composition.

7. The method according to claim 1, wherein a concentration of the first solvent ranges from greater than 60 wt. % to 99 wt. % based on a total weight of the developer composition.

8. The method according to claim 1, wherein a concentration of the organic acid is 0.001 wt. % to 30 wt. % based on a total weight of the developer composition.

9. The method according to claim 1, wherein the developer composition further comprises water or ethylene glycol at a concentration of 0.001 wt % to 30 wt. % based on a total weight of the developer composition.

10. The method according to claim 1, further comprising extending the pattern in the photoresist layer into the substrate.

11. A method, comprising:
forming a resist layer over a substrate;
patternwise crosslinking the resist layer to form a latent pattern in the resist layer including a crosslinked portion and an uncrosslinked portion of the resist layer; and
developing the latent pattern by applying a developer composition to remove the uncrosslinked portion of the resist layer to form a pattern of the crosslinked portion of the resist layer,
wherein the developer composition comprises:
a first solvent having Hansen solubility parameters of 18>δ_{d}>3, 7>δₚ>1, and 7>δₕ>1;
an organic acid having an acid dissociation constant, pKa, of −11<pKa<4; and
a Lewis acid,
wherein the organic acid and the Lewis acid are different.

12. The method according to claim 11, wherein the developer composition further comprises a second solvent having Hansen solubility parameters of 25>δ_{d}>13, 25>δₚ>3, and 30>δₕ>⁴, and
wherein the first solvent and the second solvent are different solvents.

13. The method according to claim 12, wherein the second solvent is one or more selected from the group consisting of propylene glycol methyl ether, propylene glycol ethyl ether, γ-butyrolactone, cyclohexanone, ethyl lactate, methanol, ethanol, propanol, n-butanol, acetone, dimethyl formamide, acetonitrile, isopropanol, tetrahydrofuran, and acetic acid.

14. The method according to claim 11, wherein the first solvent is one or more selected from the group consisting of n-butyl acetate, methyl n-amyl ketone, hexane, heptane, and amyl acetate.

15. The method according to claim 11, wherein the organic acid is one or more selected from the group consisting of ethanedioic acid, methanoic acid, 2-hydroxypropanoic acid, 2-hydroxybutanedioic acid, citric acid, uric acid, trifluoromethanesulfonic acid, benzenesulfonic acid, ethanesulfonic acid, methanesulfonic acid, oxalic acid, and maleic acid.

16. The method according to claim 11, wherein the Lewis acid is one or more selected from the group consisting of Sc(CF₃SO₃)₃, Y(CF₃SO₃)₃, and Ln(CF₃SO₃)₃, where Ln is La, Ce, Pr, Nd, Sm, Eu, Gd, Tb, Dy, Ho, Er, Tm, Yb, and Lu.

17. A developer composition, comprising:
a first solvent having Hansen solubility parameters of 18>δ_{d}>3, 7>δₚ>1, and 7>δₕ>1;
an organic acid having an acid dissociation constant, pKa, of −11<pKa<4; and
a Lewis acid,
wherein the organic acid and the Lewis acid are different.

18. The developer composition of claim 17, further comprising a second solvent having Hansen solubility parameters of 25>δ_{d}>13, 25>δₚ>3, and 30>δₕ>4, and
wherein the first solvent and the second solvent are different solvents.

19. The developer composition of claim 17, wherein the Lewis acid includes one or more ions selected from the group consisting of Li⁺, Na⁺, K⁺, Be²⁺, Mg²⁺, Ca²⁺, Sr²⁺, Sn²⁺, Al³⁺, Se³⁺, Ca³⁺, In³⁺, La³, Cr³⁺, Co³, Fe³⁺, As³⁺, Ir³⁺, Sc³⁺, Y³⁺, Yb³⁺, Ln³⁺ Si⁴⁺, Ti⁴⁺, Zr⁴⁺, Th⁴⁺, Pu⁴⁺, VO²⁺, UO₂²⁺, (CH₃)₂Sn²⁺, RPO²⁺, ROPO²⁺, RSO²⁺, ROSO²⁺, SO₃²⁻, I₇⁻, I₅⁻, CI₅⁻, R₃C⁺, RCO⁺, NC⁺, Fe²⁺, Co²⁺, Ni²⁺, Cu²⁺, Zn²⁺, NO⁺, Cu⁺, Ag⁺, Au⁺, Tl⁺, Hg⁺, Cs⁺, Pd²⁺, Cd²⁺, Pt²⁺, CH₃Hg²⁺, Tl³⁺, Tl(CH₃)³⁺, RH³⁺, RS⁺, RSe⁺, RTe⁺, I⁻, Br⁻, OH⁻, RO²⁺, and I⁻, or one or more compounds selected from the group consisting of I₂, Br₂, SO₂, Be(CH₃)₂, BF₃, BCl₃, BBr₃, B(OR)₃, Al(CH₃)₃, Ga(CH₃)₃, In(CH₃)₃, and B(CH₃)₃, where R is a C1-C4 alkyl group.

20. The developer composition of claim 19, wherein the Lewis acid includes one or more selected from the group consisting of Sc(CF₃SO₃)₃, Y(CF₃SO₃)₃, and Ln(CF₃SO₃)₃, where Ln is La, Ce, Pr, Nd, Sm, Eu, Gd, Tb, Dy, Ho, Er, Tm, Yb, and Lu.
